(19) United States
(12) Patent Application Publication
(10) Pub. No.: US 2025/0273511 A1
(43) Pub. Date: Aug. 28, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kai-Fang Cheng, Taoyuan City (TW); Wei-Chen Chu, Taichung City (TW); Chia-Tien Wu, Taichung City (TW); Hsiao-Kang Chang, Hsinchu City (TW)

(73) Assignee: Taiwan Semiconductor Manufacturing Company, Ltd., Hsinchu (TW)

(21) Appl. No.: 18/590,911

(22) Filed: Feb. 28, 2024

(51) Int. Cl. H01L 21/768; H01L 23/532

(52) U.S. Cl. CPC H01L 21/76831; H01L 21/76843; H01L 21/76864; H01L 21/76871; H01L 23/53238

(57) ABSTRACT

A semiconductor structure includes an interconnect structure including a first metallic pattern and a metal oxide layer. The first metallic pattern is disposed in a first opening of a dielectric layer and includes a first barrier layer lining the first opening and a first conductive layer over the first barrier layer. A top surface of the first conductive layer is between a top surface and a bottom surface of the dielectric layer. The metal oxide layer is on the top surface of the first conductive layer, and a top surface of the metal oxide layer is substantially leveled with the top surface of the dielectric layer.

### BACKGROUND

The semiconductor industry has experienced rapid growth due to continuous improvement in integration density of various components, e.g., transistors, diodes, resistors, capacitors, etc. For the most part, this improvement in integration density has come from successive reductions in minimum feature size, which allows more components to be integrated into a given area. Technological advances in integrated circuit (IC) design have produced generations of ICs where each generation has smaller and more complex circuit designs than the previous generation. There is continuous effort in developing new mechanisms of forming semiconductor devices having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 illustrate schematic cross-sectional views of intermediate steps during a process for forming a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As technology has progressed, the demand for smaller semiconductor devices with improved performance has increased. To reduce the RC time delay, low dielectric constant (low-k) materials and copper interconnects are being used in the semiconductor device. Advantages of using copper interconnects include abilities to operate faster and to form finer conductive lines, because copper has lower resistivity and increased electro-migration resistance. Combining copper interconnects with low-k dielectric materials may increase interconnect speed by reducing the RC time delay. Since copper easily diffuses into low-k dielectric materials, a diffusion barrier layer and a seed layer may be formed to separate the low-k dielectric materials and the plated copper layer. Some metals are used during the formation of the diffusion barrier and the seed layers. However, there are some challenges in using the metals in the copper interconnects, because these metals in the copper interconnects cause high resistance, thereby increasing resistance in the interconnect structure and increasing RC delay.

Embodiments discussed herein are to provide a semiconductor device including an interconnect structure and a method for forming the same. The intermediate stages of forming the semiconductor device are illustrated. For example, during the formation of the interconnect structure, separate two-times anneal processes are performed, and the elemental manganese (Mn) may diffuse to the surfaces of the metallic patterns in the interconnect structure and react with oxygen (O₂) in the native oxide, thus removing the manganese alloy from the copper (Cu) interconnects. In this manner, the RC time delay in the interconnect structure may be reduced. In some embodiments, a manganese oxide (MnOx) layer may be formed on the surfaces of the metallic patterns after the reduction/oxidation reactions and may act as a capping layer (or an etch stop layer) on the metallic patterns. Since the MnOx layer can function as the capping layer, there is no need to form additional capping (or etch stop) layer in the interconnect structure, and the capacitance in the interconnect structure may be reduced. The variations of the embodiments are discussed. Throughout the various views and illustrative embodiments, like reference numbers are used to designate like elements.

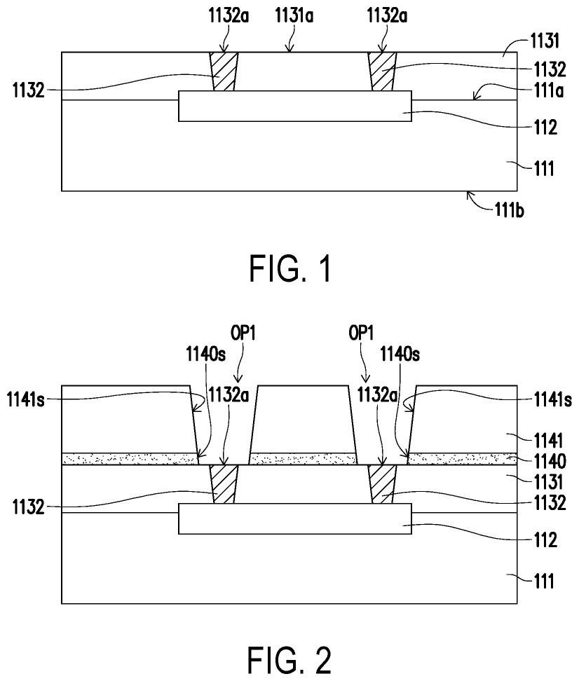

FIGS. 1-11 illustrate schematic cross-sectional views of intermediate steps during a process for forming a semiconductor device, in accordance with some embodiments. Referring to FIG. 1, a semiconductor substrate 111 including a front side 111a and a back side 111b opposite to the front side 111a may be provided. The semiconductor substrate 111 may be a substrate of silicon, doped or undoped, or an active layer of a semiconductor-on-insulator (SOI) substrate. The semiconductor substrate 111 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other suitable substrate (e.g., a multi-layered substrate, a gradient substrate, or a dielectric substrate, etc.) may be used. The semiconductor substrate 111 may be provided in a wafer form, a chip form, a panel form, etc., and may (or may not) be singulated in the subsequent processes.

In some embodiments, one or more integrated circuit (IC) device(s) 112 may be formed in/on the semiconductor substrate 111. For example, the IC devices 112 are formed at the front side 11a of the semiconductor substrate 111. The IC devices 112 may be or include active devices (e.g., transistors, diodes, etc.), passive devices (e.g., capacitors, resistors, inductors, etc.), a combination thereof, or the like. In some embodiments, the IC devices 112 are formed using suitable Front-end-of-line (FEOL) process and may be referred to as the FEOL devices. In alternative embodiments, the semiconductor substrate 111 and the structure formed thereon is used for forming interposer(s). In such embodiments, no active devices (e.g., transistors and diodes) are formed in/on the semiconductor substrate 111. There may (or may not) be passive devices (e.g., capacitors, resistors, inductors, or the like) formed in/on the semiconductor substrate 111. The details of the IC devices 112 are not illustrated herein. In some embodiments, through-vias (not shown) may be formed to penetrate through the semiconductor substrate 111 to interconnect the IC devices 112 on the opposite sides of the semiconductor substrate 111.

With continued reference to FIG. 1, an inter-layer dielectric (ILD) layer 1131 and conductive plugs 1132 may be formed over the front side 111a of the semiconductor substrate 111. The ILD layer 1131 may surround and cover the IC devices 112. In some embodiment where the IC devices 112 include transistors, the ILD layer 1131 fills the space between the gate stacks of the transistors. The ILD layer 1131 may include one or more dielectric sublayers formed of materials such as Phospho-Silicate Glass (PSG), Boro-Silicate Glass (BSG), Boron-Doped Phospho-Silicate Glass (BPSG), undoped Silicate Glass (USG), the like, combinations thereof, or the like. The conductive plugs 1132 may extend through the ILD layer 1131 to electrically and physically couple to the IC devices 112. In some embodiment where the IC devices 112 include transistors, the conductive plugs 1132 couple the gates and source/drain regions of the transistors. The conductive plugs 1132 may be formed of tungsten, cobalt, nickel, copper, silver, gold, aluminum, the like, alloy, combinations thereof, etc. In some embodiments, the ILD layer 1131 and the conductive plugs 1132 are formed using suitable Middle-end-of-line (MEOL) process. For example, the formation of the conductive plugs 1132 includes: etching the ILD layer 1131 to form openings, filling one or more conductive material(s) into the openings, and performing a planarization (e.g., chemical mechanical polishing (CMP), grinding, etching, a combination thereof, etc.) to level the top surfaces 1132a of the conductive plugs 1132 with the top surface 1131a of the ILD layer 1131.

Referring to FIG. 2 and with reference to FIG. 1, a first dielectric sublayer 1141 with openings OP1 may be formed over the ILD layer 1131. The first dielectric sublayer 1141 may be referred to as inter-metal dielectric (IMD) layer. The first dielectric sublayer 1141 may be a single layer or a multi-layered structure. In some embodiments, the first dielectric sublayer 1141 is formed of a low-k dielectric material, an extreme low-k dielectric material, a porous low-k dielectric layer, and combinations thereof. The dielectric constant (k value) of the first dielectric sublayer 1141 may be in a range of about 2.0 and about 5.0. Other k value may be possible. For example, the first dielectric sublayer 1141 includes SiOₓ, SiOₓC_{y}H_{z}, SiOₓC_{y}, SiCₓ, SiCₓN_{y}, the like, a combination thereof, or any suitable dielectric material.

In some embodiments, a layer of first dielectric sublayer is deposited over the ILD layer 1131 and the conductive plugs 1132 by chemical vapor deposition (CVD), atomic layer deposition (ALD), spin-coating, or the like, and the deposition temperature for forming the layer of first dielectric sublayer may be lower than 425° C. An additional thermal treatment (e.g., annealing or UV process) may (or may not) be performed after the deposition process. In some embodiments, the openings OP1 in the first dielectric sublayer 1141 are formed using lithography and etching operations or any suitable removal process. The top surfaces 1132a of the contact plugs 1132 may be partially or fully exposed by the openings OP1. The openings OP1 may have the same size or have different size, depending on circuit design. It should be noted that the openings OP1 illustrated as single-damascene openings are merely examples and may be formed as dual-damascene openings, in accordance with other embodiments.

In some embodiments, an etch stop layer 1140 is formed over the ILD layer 1131 before forming the first dielectric sublayer 1141. For example, a layer of etch stop material and a layer of dielectric material are sequentially formed on the top surface 1131a of the ILD layer 1131, and the openings OP1 may be formed to penetrate through the layers of etch stop material and dielectric material to form the etch stop layer 1140 and the first dielectric sublayer 1141. The respective opening OP1 may be defined by the inner sidewalls (1140s and 1141s) of the etch stop layer 1140 and the first dielectric sublayer 1141. The inner sidewalls (1140s and 1141s) may be slanted or substantially vertical. The etch stop layer 1140 may be a single layer or a composite layer including a plurality of sublayers formed of different materials. For example, the etch stop layer 1140 includes SiCₓN_{y}, AlNₓ, AlOₓN_{y}, AlOₓ, AlOₓC_{y}, BₓN_{y}, BCₓN_{y}, a combination thereof, the like, or any suitable material. The etch stop layer 1140 may be formed of a material that has a high etching selectivity with the first dielectric sublayer 1141, and hence the etch stop layer 1140 may be used to stop the etching of the first dielectric sublayer 1141. Alternatively, the etch stop layer 1140 is omitted.

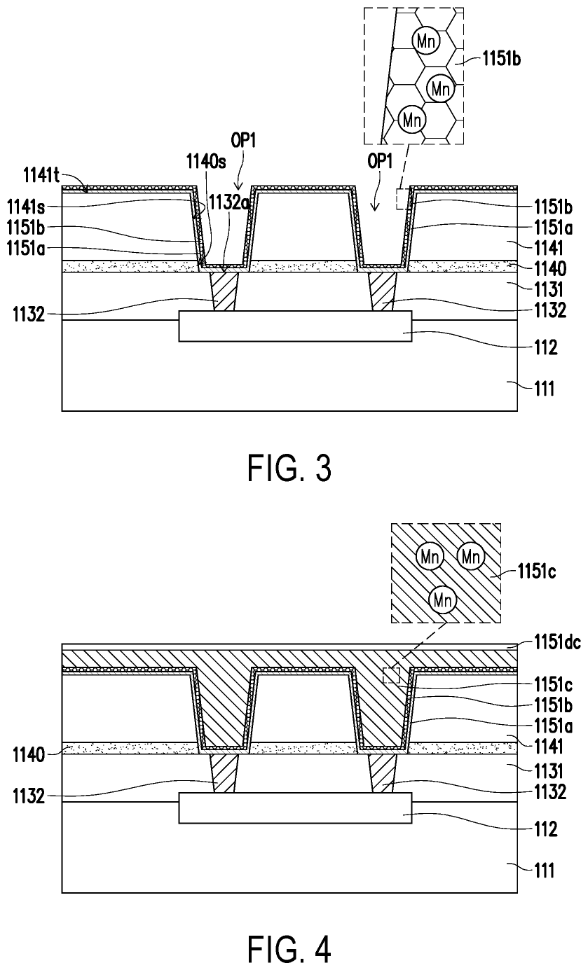

Referring to FIG. 3 and with reference to FIG. 2, a barrier material layer 1151a may be conformally formed on the first dielectric sublayer 1141 and in the openings OP1. For example, the barrier material layer 1151a is a liner lining the top surface 1141t of the first dielectric sublayer 1141 and the inner sidewalls (1140s and 1141s) of the etch stop layer 1140 and the first dielectric sublayer 1141. The barrier material layer 1151a may be conductive and in physical contact with the top surfaces 1132a of the conductive plugs 1132 which are exposed by the openings OP1. In some embodiments, the barrier material layer 1151a is configured to block/reduce diffusion of the metal element present in the overlying layer to the first dielectric sublayer 1141. For example, the barrier material layer 1151a includes titanium (Ti), titanium nitride (TiN), tantalum (Ta), tantalum nitride (TaN), or the like.

In some embodiments, a seed material layer 1151b is conformally formed on the barrier material layer 1151a. The seed material layer 1151b may be a copper-containing material layer that aids in the formation of a thicker layer during subsequent processing steps. In some embodiments, the seed material layer 1151b is a Ti/Cu bilayer which includes a Ti film overlying the barrier material layer 1151a and a Cu film overlying the Ti film. For example, the seed material layer 1151b is formed by physical vapor deposition (PVD) such as e.g., sputtering, evaporation, etc. Other suitable methods (e.g., CVD, ALD, electro-deposition, or electroless deposition, etc.) may be used, in accordance with some other embodiments.

With continued reference to FIG. 3, the seed material layer 1151b may be alloyed with a material (e.g., manganese (Mn) or the like) that improves the adhesive properties of the seed material layer 1151b. For example, the alloying material (e.g., Mn or the like) is introduced during formation of the seed material layer 1151b (e.g., during the PVD process). In some embodiments, by using a sputtering target containing a copper-manganese alloy during the PVD process, Mn may be incorporated into the copper-containing seed material layer 1151b. The seed material layer 1151b may be viewed as a copper-manganese (Cu—Mn) layer. The ratio of Mn to Cu contained in the seed material layer 1151b is not limited in the disclosure. In alternative embodiments, an additive metal (e.g., Ti, Al, Cr, and/or the like) is used for forming the seed material layer 1151b depending on circuit and process requirements. It should be noted that Mn atoms illustrated in the dashed box of FIG. 3 are merely intended to be schematic and are not intended to limit the embodiments.

Referring to FIG. 4 and with reference to FIG. 3, a conductive material layer 1151c may be formed on the seed material layer 1151b and fill the openings OP1. In some embodiments, a deposition process (e.g., electro-chemical plating (ECP), electroless deposition (ELD), ALD, CVD, PVD, or the like) is carried out to form the conductive material layer 1151c. The conductive material layer 1151c may include substantially pure elemental Cu, Cu-containing unavoidable impurities, and Cu alloys containing minor amounts of elements such as Mn, Ta, Ti, Al, Cr, or the like. In some embodiments, the Mn existed in the seed material layer 1151b diffuses into the conductive material layer 1151c.

The Mn atoms shown in the dashed box of FIG. 4 may come from diffusion from the seed material layer 1151d and/or deposition of conductive material layer 1151c. The top surface of the conductive material layer 1151c may be oxidized when it is exposed to an ambient environment (or air) to form a first metal oxide layer 1151dc. As used herein, a layer of a metal oxide consists essentially of atoms of a metal. In some embodiments, the first metal oxide layer 1151dc is a native oxide layer. For example, when the conductive material layer 1151c is formed of Cu, Cu of the conductive material layer 1151c reacts with oxygen in an ambient environment (or air), and the first metal oxide layer 1151dc (e.g., copper oxidation (CuOx) layer) may then be formed.

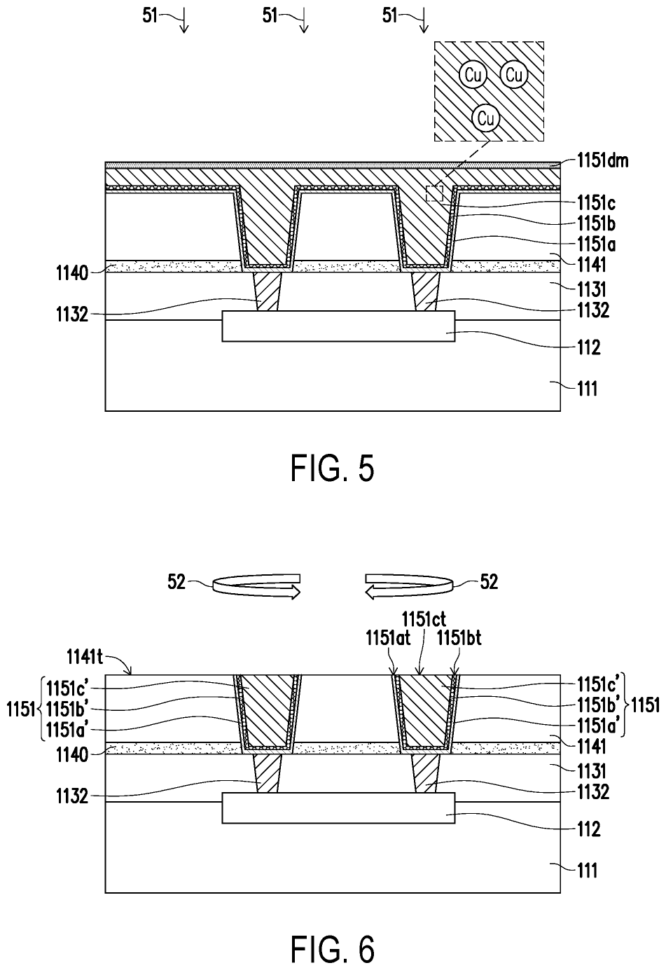

Referring to FIG. 5 and with reference to FIG. 4, a first thermal treatment 51 (e.g., an annealing process or the like) may be performed on the structure shown in FIG. 4. During the first thermal treatment 51 with inert gas (e.g., Ar, N₂, or the like) ambient, the structure shown in FIG. 4 may be heated to the annealing temperature less than 425° C. (e.g., in the range between about 250° C. and about 450° C.). The duration of the first thermal treatment 51 may be in the range between about 1 minute and about 10 minutes. In some embodiments, during the first thermal treatment 51, the first metal oxide layer 1151dc is reduced, forming a second metal oxide layer 1151dm. During the first thermal treatment 51, a reduction/oxidation reaction occurs between the elemental Mn dispersed in the conductive material layer 1151c and the first metal oxide layer 1151dc (e.g., CuOx layer) to regenerate the elemental Cu while oxidizing at least a portion of the elemental Mn. Since the metal element Mn has a higher reactivity with oxygen (e.g., requires less energy to react with oxygen) relative to the metal element Cu, the elemental Mn present of the conductive material layer 1151c may act as a reducing agent. The elemental Mn undergoes oxidation and reduces the elemental Cu present of the first metal oxide layer 1151dc (e.g., CuOx layer). As shown in the dashed boxes of FIGS. 4-5, the elemental Mn in FIG. 4 may be replaced with the elemental Cu. In some embodiments, during/after the first thermal treatment 51, the elemental Mn is oxidized to a manganese oxidation (MnOx) layer (e.g., the second metal oxide layer 1151dm), where the oxygen originates from the first metal oxide layer 1151dc.

Referring to FIG. 6 and with reference to FIG. 5, a planarization process 52 (e.g., CMP, grinding, etching, a combination thereof, etc.) may be performed on the structure shown in FIG. 5 to remove excess materials overlying the first dielectric sublayer 1141. During the planarization process 52, the second metal oxide layer 1151dm may be removed. Portions of the conductive material layer 1151c, the seed material layer 1151b, and the barrier material layer 1151a that cover the top surface 1141t of the first dielectric sublayer 1141 may also be removed. In some embodiments, after the planarization process 52, the top surface 1141t of the first dielectric sublayer 1141 is substantially leveled (or coplanar) with the top surface 1151at of the barrier layer 1151a′, the top surface 1151bt of the seed layer 1151b′, and the top surface 1151ct of the conductive layer 1151c′, within process variations. The barrier layer 1151a′, the seed layer 1151b′, and the conductive layer 1151c′ may be collectively viewed as a first metallic pattern 1151.

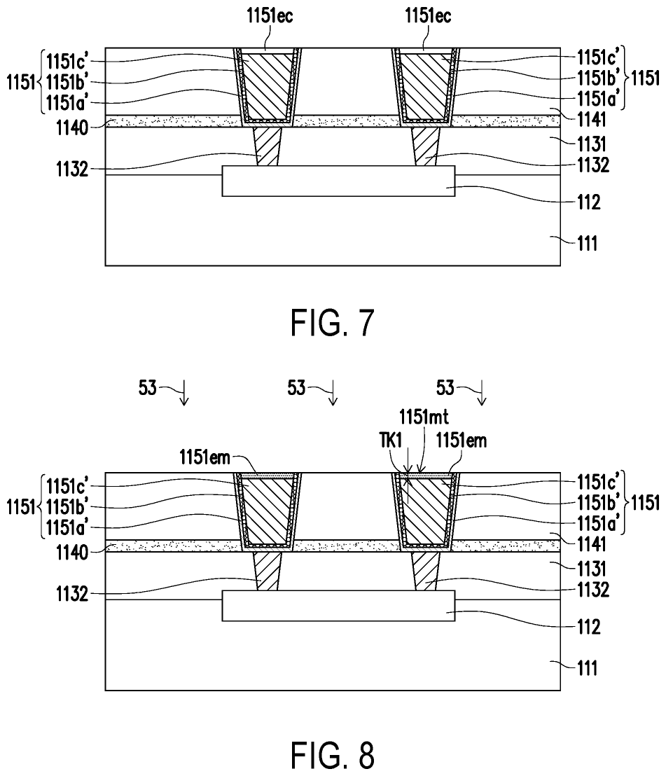

Referring to FIG. 7 and with reference to FIG. 6, a third metal oxide layer 1151ec may be formed by the metal of the first metallic pattern 1151 reacting with oxygen in an ambient environment (or air). In some embodiments, the third metal oxide layer 1151ec is a native oxide layer. For example, during/after the planarization process 52, the structure of FIG. 6 is exposed to an ambient (or air) that contains oxygen, the conductive layer 1151c′ including the elemental Cu may react with oxygen to form a copper oxidation (CuOx) layer (e.g., the third metal oxide layer 1151ec). Since the third metal oxide layer 1151ec is formed by exposing the structure to an ambient (air) instead of depositing a layer of metal oxide on the structure, the top surface of the third metal oxide layer 1151ec may be substantially the same as the top surface 1151ct of the conductive layer 1151c′ labeled in FIG. 6, and may be substantially leveled (or coplanar) with the top surface 1141t of the first dielectric sublayer 1141 as described in FIG. 6. In the cross-sectional view, the third metal oxide layer 1151ec may be laterally covered by the seed layer 1151b′ and/or the barrier layer 1151a′.

Referring to FIG. 8 and with reference to FIG. 7, a second thermal treatment 53 (e.g., an annealing process or the like) may be performed on the structure shown in FIG. 7. During the second thermal treatment 53 with inert gas (e.g., Ar, N₂, or the like) ambient, the structure shown in FIG. 7 may be heated to the annealing temperature less than 425° C. (e.g., in the range between about 250° C. and about 450° C.). The duration of the second thermal treatment 53 may be in the range between about 1 minute and about 10 minutes. In some embodiments, during the second thermal treatment 53, the third metal oxide layer 1151ec is reduced, forming a fourth metal oxide layer 1151em. Similar to the description associated with FIG. 5, during the second thermal treatment 53, a reduction/oxidation reaction occurs between the elemental Mn remaining in the conductive layer 1151c′ and the third metal oxide layer 1151ec (e.g., CuOx layer) to regenerate elemental Cu while oxidizing at least a portion of the elemental Mn.

The elemental Mn in the conductive layer 1151c′ may function as a reducing agent, and the elemental Mn undergoes oxidation and reduces the elemental Cu present of the third metal oxide layer 1151ec (e.g., CuOx layer). For example, after the second thermal treatment 53, the elemental Mn remaining in the conductive layer 1151c′ is oxidized to a manganese oxidation (MnOx) layer (e.g., the fourth metal oxide layer 1151em), where the oxygen originates from the third metal oxide layer 1151ec. After the reduction/oxidation reactions, the conductive layer 1151c′ may have a lower Mn atomic percentage than the fourth metal oxide layer 1151em (e.g., MnOx layer). The thickness TK1 of the fourth metal oxide layer 1151em may be controlled by adjusting the process recipe. For example, the higher the temperature of the annealing process, the thicker the fourth metal oxide layer 1151em becomes. In some embodiments, the fourth metal oxide layer 1151em has the thickness TK1 ranging from about 10 angstroms to about 20 angstroms. Other value of the thickness TK1 may be possible.

Since the fourth metal oxide layer 1151em is formed by a reduction/oxidation reaction instead of deposition of a layer of metal oxide on the structure, the top surface 1151mt of the fourth metal oxide layer 1151em may be substantially the same as the top surface of the third metal oxide layer 1151ec, and may be substantially leveled (or coplanar) with the top surface 1141t of the first dielectric sublayer 1141 labeled in FIG. 6. In the cross-sectional view, the fourth metal oxide layer 1151em may be laterally covered by the seed layer 1151b′ and/or the barrier layer 1151a′. The fourth metal oxide layer 1151em may serve as a capping layer (or an etch stop layer/an insulator) of the first metallic pattern 1151 so that there is no need to form additional capping (or etch stop) layer on the first metallic pattern 1151. It has been observed that by forming the fourth metal oxide layer 1151em using the aforementioned steps, the capacitance of the first metallic pattern 1151 may be reduced to 5% to 10% approximately, compared to the process without performing the two-times annealing processes. Since the first metallic pattern 1151 has been undergone separate two-times thermal treatments (e.g., 51 and 53), the reduction/oxidation reactions occur during the thermal treatments to oxidize the elemental Mn and regenerate elemental Cu in the first metallic pattern 1151. The atomic percentage of Mn in the first metallic pattern 1151 may be significantly decreased. For example, the atomic percentage of the metal element Mn which residues in the first metallic pattern 1151 is in a range of about 0.5% and 3%. The first metallic pattern 1151 may thus have lower resistance; thereby reducing the RC time delay and increasing interconnect speed.

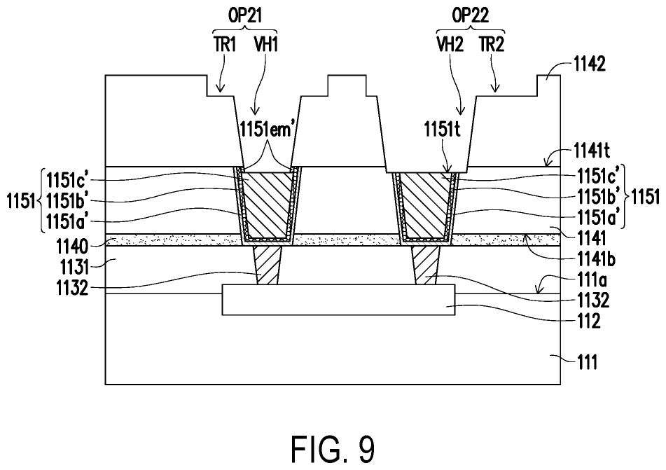

Referring to FIG. 9 and with reference to FIG. 8, a second dielectric sublayer 1142 with openings (e.g., OP21 and OP22) may be formed over the first dielectric sublayer 1141. The material and the forming method of the second dielectric sublayer 1142 with the openings (e.g., OP21 and OP22) may be similar to those of the first dielectric sublayer 1141 with the openings OP1 described in FIG. 2, and thus the details thereof are not repeated herein. The openings of the second dielectric sublayer 1142 may have different sizes or may be substantially identical. In some embodiments, the openings of the second dielectric sublayer 114 includes a first opening OP21 and a second opening OP22, where the first opening OP21 has a smaller bottom and the second opening OP22 has a larger bottom. The first and second openings (OP21 and OP2) may be dual-damascene openings. Although the embodiments illustrate dual-damascene openings (OP21 and OP22) in the second dielectric sublayer 1142, the use of single-damascene openings in the second dielectric sublayer 1142 also provide values.

In some embodiments, the first opening OP21 includes a first trench TR1 and a first via-hole VH1 underlying and connected to the first trench TR1, and the second opening OP22 includes a second trench TR2 and a second via-hole VH2 underlying and connected to the second trench TR2. In some embodiments, the first via-hole VH1 and/or the second via-hole VH2 may have a tapered profile with a wider top and a narrower bottom. Alternatively, the first via-hole VH1 and/or the second via-hole VH2 may have a substantially vertical sidewall. In some embodiments, the bottom size of the second via-hole VH2 is different from the bottom size of the first via-hole VH1. For example, during/after the formation of the first via-hole VH1, a portion of the fourth metal oxide layer 1151em is removed to accessibly expose the conductive layer 1151c′ for further electrical connection. As shown in FIG. 9, the remaining portion of the fourth metal oxide layer 1151em forms a capping layer 1151em′ encircling the bottom of the first via-hole VH1.

In some embodiments, during/after the formation of the second via-hole VH2, the fourth metal oxide layer 1151em is fully removed to accessibly expose the conductive layer 1151c′ for further electrical connection. Depending on the bottom size of the second via-hole VH2, a portion of the first dielectric sublayer 1141 in proximity to the removed fourth metal oxide layer 1151em may also be removed during/after the formation of the second via-hole VH2 to accessibly expose the barrier layer 1151a′, the seed layer 1151b′, and the conductive layer 1151c′. In some embodiments, the top surface 1151t of the first metallic pattern 1151 exposed by the second opening OP22 is lower than the top surface 1141t of the first dielectric sublayer 1141, relative to the front side 111a of the semiconductor substrate 111. For example, the top surface 1151t of the first metallic pattern 1151 is between the top surface 1141t and the bottom surface 1141b of the first dielectric sublayer 1141. It should be noted that the openings (OP21 and OP22) may have a different configuration than shown.

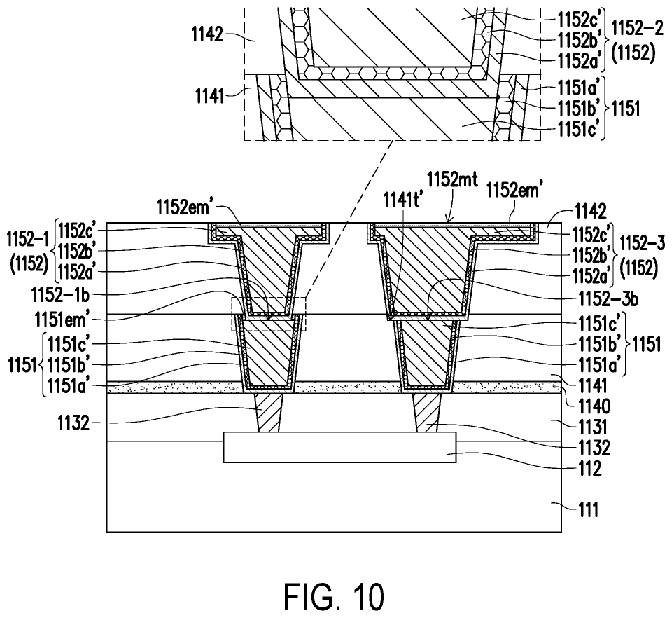

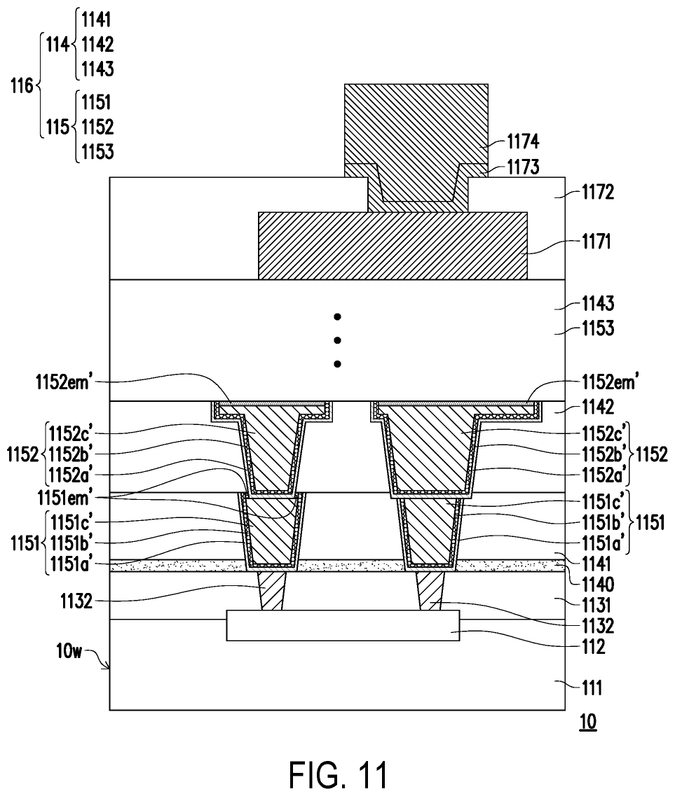

Referring to FIG. 10 and with reference to FIG. 9, a second metallic pattern 1152 may be formed in the openings (e.g., OP21 and OP22) of the second dielectric sublayer 1142 to be connected to the first metallic pattern 1151. The processes described in FIGS. 3-8 may be repeated to form the second metallic pattern 1152, and thus the details of the formation of the second metallic pattern 1152 are not repeated herein. In some embodiments, the second metallic pattern 1152 includes a barrier layer 1152a′ lining the openings (e.g., OP21 and OP22), a seed layer 1152b′ overlying the barrier layer 1152a′, and a conductive layer 1152c′ overlying the seed layer 1152b′. In some embodiments, a capping layer 1152em′ formed on the top of the second metallic pattern 1152. The barrier layer 1152a′, the seed layer 1152b′, the conductive layer 1152c′, and the capping layer 1152em′ may respectively similar to the barrier layer 1151a′, the seed layer 1151b′, the conductive layer 1151c′, and the capping layer 1151em′.

For a first portion 1152-1 of the second metallic pattern 1152 formed in the first opening OP21, a bottom surface 1152-1b of the first portion 1152-1 may be in physical and electrical contact with the underlying first metallic pattern 1151. The bottom of the first portion 1152-1 may be in lateral and physical contact with the capping layer 1151em′. For example, the bottom of the first portion 1152-1 is laterally spaced apart from the seed layer 1151b′ of the first metallic pattern 1151 by the capping layer 1151em′. The bottom of the first portion 1152-1 may be laterally spaced apart from the second dielectric sublayer 1142 at least by the capping layer 1151em′. In some embodiments, the bottom surface 1152-1b is laterally surrounded/covered by the capping layer 1151em′. The bottom surface 1152-1b of the first portion 1152-1 may be less than the top surface of the conductive layer 1151c′.

In some embodiments, the first portion 1152-1 is replaced with a second portion 1152-2 of the second metallic pattern 1152 shown in the bashed box of FIG. 10. The difference between the first portion 1152-1 and the second portion 1152-2 may include that the capping layer 1151em′ is completely removed after the formation of the first opening OP21 (labeled in FIG. 9), and the barrier layer 1152a′ of the second portion 1152-2 may be in physical, vertical, and electrical contact with the conductive layer 1151c′. In some embodiments, the barrier layer 1152a′ of the second portion 1152-2 has a lower portion which is in lateral and physical contact with the seed layer 1151b′ and an upper portion which is in lateral and physical contact with the second dielectric sublayer 1142. In some other embodiments, during the removal of the capping layer 1151em′ to form the first opening OP21 (labeled in FIG. 9), not only the capping layer 1151em′ is completely removed but also the seed layer 1151b′ surrounding the capping layer 1151em′ is partially (or fully) removed. For example, the bottom of the barrier layer 1152a′ of the second portion 1152-2 may be in lateral and physical contact with the barrier layer 1151a′ of the first metallic pattern 1151.

For a third portion 1152-3 of the second metallic pattern 1152 formed in the second opening OP22, a bottom surface 1152-3b of the third portion 1152-3 may be in physical and electrical contact with the underlying first metallic pattern 1151. In some embodiments, the bottom surface 1152-3b of the third portion 1152-3 is in physical contact with the surface 1141t′ of the first dielectric sublayer 1141 which is leveled with the top surface 1151t of the first metallic pattern 1151. The bottom of the third portion 1152-3 may be in lateral and physical contact with the second dielectric sublayer 1142. In some embodiments, the top surface 1141t of the first dielectric sublayer 1141 is between the bottom surface 1152-3b of the third portion 1152-3 (or the bottom surface 1152-1b of the first portion 1152-1) and the top surface 1152mt of the capping layer 1152em′. It should be noted that the first/second/third portions (1152-1/1152-2/1152-3) of the second metallic pattern 1152 and the corresponding first metallic pattern 1151 may be arbitrarily formed in any suitable combination manner and at any level of the interconnect structure. In addition, the first and second metallic patterns (1151 and 1152) shown in FIG. 10 are merely examples and may have a different configuration than shown.

Referring to FIG. 11 and with reference to FIG. 10, the processes described in FIGS. 9-10 may be repeated to form more dielectric sublayers 1143 and metallic patterns 1153 over the second dielectric sublayer 1142 and the second metallic pattern 1152, and thus the details of the formation of the dielectric sublayers 1143 and metallic patterns 1153 are not repeated herein. In addition, the omission of the details of dielectric sublayers 1143 and metallic patterns 1153 is represented by dots. It is appreciated that the number of metallic patterns and the number of dielectric sublayers are dependent upon the design of the semiconductor device and construe no limitation in the disclosure. In some embodiments, the dielectric sublayers 1143 and the underlying first and second dielectric sublayers (1141 and 1142) are collectively viewed as an interconnect dielectric layer 114, and the metallic patterns 1153 and the underlying first and second metallic patterns (1151 and 1152) are collectively viewed as an interconnect pattern 115. The interconnect dielectric layer 114 and the interconnect pattern 115 embedded in the interconnect dielectric layer 114 may be collectively viewed as an interconnect structure 116. In some embodiments, suitable Back-end-of-line (BEOL) processes are performed as described in FIGS. 3-11 to form the interconnect structure 116, and the interconnect structure 116 may be referred to as the BEOL structure.

In some embodiments, one or more contact pad(s) 1171 is formed on the topmost one of the dielectric sublayers 1143 and is in physical and electrical contact with the topmost one of the metallic patterns 1153. The contact pads 1171 may be aluminum pads, Al—Cu pads, copper pads, and/or the like. In some embodiments, a passivation layer 1172 is formed on the topmost one of the dielectric sublayers 1143 and covering the contact pads 1171. For example, the passivation layer 1172 includes one or more layer(s) of silicon oxide, silicon nitride, silicon oxynitride, the like, or a combination thereof. The passivation layer 1172 may include one or more opening(s) accessibly exposing at least a portion of the contact pads 1171 for further electrical connection. In some embodiments, one or more conductive bump(s) 1174 is formed in the openings of the passivation layer 1172 and is in electrical contact with the underlying contact pads 1171. The conductive bumps 1174 may be controlled collapse chip connection (C4) bumps, ball grid array (BGA) connectors, solder balls, metal pillars, micro-bumps, electroless nickel-electroless palladium-immersion gold (ENEPIG) formed bumps, or the like. The respective conductive bump 1174 may include a conductive material such as solder, copper, aluminum, gold, nickel, silver, palladium, tin, the like, or a combination thereof. In some embodiments, the respective conductive bump 1174 has a substantially vertical sidewall.

In some other embodiments, the respective conductive bump 1174 includes solder material and may be reflowed to form a generally spherical solder bump. In alternative embodiments, the respective conductive bump 1174 includes a pillar portion (e.g., a copper pillar) and a cap portion formed on the pillar portion, where the pillar portion has a substantially vertical sidewall and the cap portion has a bump profile. In some embodiments, one or more under bump metallization (UBM) layer 1173 is formed on the contact pads 1171 and in the opening of the passivation layer 1172, and then the conductive bumps 1174 may be formed on the UBM layer 1173. For example, the conductive bumps 1174 are formed by placing solder balls on the UBM layer 1173 and then reflowing the solder balls or performing a plating step to form solder regions over the UBM layer 1173 and then reflowing the solder regions. Other methods may be used to form the UBM layer 1173 and the conductive bumps 1174. Alternatively, the UBM layer 1173 is omitted.

With reference to FIG. 11, the aforementioned processes may be performed in wafer level, and a singulation process is optionally performed by cutting along scribe lines to form individual semiconductor device 10. In some embodiments, the scribe lines vertically pass through the passivation layer 1172, the interconnect dielectric layer 114, the etch stop layer 1140 (if present), the ILD layer 1131, and the semiconductor substrate 111 to form a continuous and singulated sidewall 10w of the semiconductor device 10. The semiconductor device 10 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), combinations thereof (e.g., a system-on-a-chip (SoC) die), or the like.

It should be noted that FIG. 11 is provided for illustrative purposes only, and the semiconductor device 10 may utilize fewer or additional elements according to some embodiments. One or more packaging/semiconductor process(es) may be performed on the semiconductor device 10 depending on product requirements. The advanced packaging technologies enable production of semiconductor device 10 with enhanced functionalities. The embodiments described herein are not intended to be limited to the embodiments described, and the embodiments may be implemented in any suitable methods and structures (e.g., integrated fanout (InFO) packages, package-on-package (PoP), chip-on-wafer-on-substrate (CoWoS) packages, system-on-integrated-circuit (Stoic) structure, or the like. All such embodiments are fully intended to be included within the scope of the embodiments.

Embodiments may have one or a combination of the following features and/or advantages. By performing separate two-times thermal treatments (e.g., anneal processes) during the formation of a layer of the metallic patterns in the interconnect structure, the elemental Mn in the layer of the metallic patterns acting as a reducing agent may undergo oxidation to form the MnOx layer. The MnOx layer may serve as a capping layer (or an etch stop layer) on the surface of the metallic patterns, so that additional etch stop/capping layer formed between adjacent dielectric sublayers may be omitted, thereby reducing capacitance in the interconnect structure. The reduction/oxidation reactions occur during the thermal treatments to oxidize the elemental Mn and also regenerate elemental Cu in the metallic patterns. In this manner, the atomic percentage of Mn in the metallic patterns may be decreased, and the metallic patterns may thus have lower resistance, thereby reducing the RC time delay and increasing interconnect performance. Accordingly, a semiconductor device with better electrical performance, improved reliability, and improved yield may be achieved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes an interconnect structure including a first metallic pattern and a metal oxide layer. The first metallic pattern is disposed in a first opening of a dielectric layer and includes a first barrier layer lining the first opening and a first conductive layer over the first barrier layer. A top surface of the first conductive layer is between a top surface and a bottom surface of the dielectric layer. The metal oxide layer is on the top surface of the first conductive layer, and a top surface of the metal oxide layer is substantially leveled with the top surface of the dielectric layer.

According to some embodiments, a semiconductor structure includes an interconnect structure over a front side of a semiconductor substrate. The interconnect structure includes a first metallic pattern, and the first metallic pattern includes a barrier layer, a seed layer conformally overlying the barrier layer, and a conductive layer overlying the seed layer. Each of the barrier layer, the seed layer, and the conductive layer includes a top surface away from the front side of the semiconductor substrate and a bottom surface closer to the semiconductor substrate than the top surface, where a top surface of the conductive layer is lower than top surfaces of the barrier layer and the seed layer, relative to the front side of the semiconductor substrate.

According to some embodiments, a manufacturing method of a semiconductor structure includes forming an interconnect structure. Forming the interconnect structure includes: forming a conductive layer in a dielectric layer; performing a first thermal treatment on the conductive layer, wherein during the first thermal treatment, a metal oxidation layer containing a first metal element at a surface of the conductive layer is reduced, forming a second metal oxide layer containing a second metal element; performing a second thermal treatment after the first thermal treatment, wherein during the second thermal treatment, another metal oxidation layer containing the first metal element and formed after the first thermal treatment is reduced, forming another metal oxide layer containing the second metal element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnect structure comprising:
a dielectric layer;
a first metallic pattern disposed in a first opening of the dielectric layer, the first metallic pattern comprising a first barrier layer lining the first opening of the dielectric layer and a first conductive layer over the first barrier layer, a top surface of the first conductive layer being between a top surface and a bottom surface of the dielectric layer; and
a metal oxide layer on the top surface of the first conductive layer, a top surface of the metal oxide layer being substantially leveled with the top surface of the dielectric layer.

2. The semiconductor device of claim 1, wherein the first barrier layer laterally separates the metal oxide layer from the dielectric layer.

3. The semiconductor device of claim 1, wherein the metal oxide layer comprises a first metal element, the first conductive layer comprises a second metal element, and the first metal element has a higher reactivity with oxygen than the second metal element.

4. The semiconductor device of claim 3, wherein an atomic percentage of the first metal element in the first metallic pattern is lower than an atomic percentage of the first metal element in the metal oxide layer.

5. The semiconductor device of claim 3, wherein the first metal element is manganese and the second metal element is copper.

6. The semiconductor device of claim 1, wherein the metal oxide layer is a manganese oxidation layer.

7. The semiconductor device of claim 1, wherein the first metallic pattern further comprises:
a first seed layer between the first barrier layer and the first conductive layer, and the first seed layer being in lateral and physical contact with the metal oxide layer.

8. The semiconductor device of claim 1, wherein the interconnect structure further comprises:
a second metallic pattern penetrating through the metal oxide layer to be in contact with the top surface of the first conductive layer.

9. The semiconductor device of claim 1, wherein:
the first metallic pattern further comprises a second seed layer lining a second opening of the dielectric layer and a second conductive layer over the second seed layer,
the interconnect structure further comprises a second metallic pattern landing on a top surface of the second conductive layer, and the second seed layer is in lateral and physical contact with the second metallic pattern.

10. The semiconductor device of claim 1, wherein:
the first metallic pattern further comprises a second barrier layer lining a second opening of the dielectric layer and a second conductive layer over the second barrier layer,
the interconnect structure further comprises a second metallic pattern landing on top surfaces of the second conductive layer and the second barrier layer which are between the top surface and the bottom surface of the dielectric layer.

11. The semiconductor device of claim 10, wherein the top surfaces of the second conductive layer and the second barrier layer are substantially leveled with each other.

12. The semiconductor device of claim 10, wherein a bottom surface of the second metallic pattern is in direct contact with the second conductive layer, the second barrier layer, and the dielectric layer.

13. A semiconductor device, comprising:
an interconnect structure over a front side of a semiconductor substrate, the interconnect structure comprising:
a first metallic pattern comprising a barrier layer, a seed layer conformally overlying the barrier layer, and a conductive layer overlying the seed layer, each of the barrier layer, the seed layer, and the conductive layer comprising a top surface away from the front side of the semiconductor substrate and a bottom surface closer to the semiconductor substrate than the top surface, wherein a top surface of the conductive layer is lower than top surfaces of the barrier layer and the seed layer, relative to the front side of the semiconductor substrate.

14. The semiconductor device of claim 13, wherein the interconnect structure further comprises:
a metal oxide layer disposed on the top surface of the conductive layer and laterally connected to the seed layer.

15. The semiconductor device of claim 14, wherein an atomic percentage of manganese in the conductive layer is lower than an atomic percentage of manganese in the metal oxide layer.

16. The semiconductor device of claim 13, wherein the interconnect structure further comprises:
a second metallic pattern landing on the first metallic pattern, wherein a bottom surface of the second metallic pattern is connected to the top surface of the conductive layer and is lower than the top surfaces of the barrier layer and the seed layer, relative to the front side of the semiconductor substrate.

17. A manufacturing method of a semiconductor device, comprising:
forming an interconnect structure comprising:
forming a conductive layer in a dielectric layer;
performing a first thermal treatment on the conductive layer, wherein during the first thermal treatment, a metal oxidation layer containing a first metal element at a surface of the conductive layer is reduced, forming a second metal oxide layer containing a second metal element; and
performing a second thermal treatment after the first thermal treatment, wherein during the second thermal treatment, another metal oxidation layer containing the first metal element and formed after the first thermal treatment is reduced, forming another metal oxide layer containing the second metal element.

18. The manufacturing method of claim 17, wherein the first metal element is copper and the second metal element is manganese.

19. The manufacturing method of claim 17, wherein forming the conductive layer in the dielectric layer comprises:
forming a seed layer in an opening of the dielectric layer, wherein the second metal element is incorporated into a material of the seed layer; and
forming a conductive material layer on the seed layer, wherein during the conductive layer is formed, the second metal element diffuses into the conductive material layer.

20. The manufacturing method of claim 17, further comprises:
performing a planarization process after the first thermal treatment and before the second thermal treatment, wherein the second metal oxide layer is removed during the planarization process.
